(19) United States
(12) Patent Application Publication
(10) Pub. No.: US 2026/0031557 A1
(43) Pub. Date: Jan. 29, 2026

(54) SYSTEMS FOR TRANSFORMER FOR INVERTER FOR ELECTRIC VEHICLE

(71) Applicant: BorgWarner US Technologies LLC, Wilmington, DE (US)

(72) Inventors: Mark Alan EBENHART, Kokomo, IN (US); Vikram MURTHY, Carmel, IN (US)

(73) Assignee: BorgWarner US Technologies LLC, Wilmington, DE (US)

(21) Appl. No.: 18/783,673

(22) Filed: Jul. 25, 2024

(51) Int. Cl. H01R 12/58; B60L 50/51; H05K 7/20

(52) U.S. Cl. CPC H01R 12/58; H05K 7/20945; B60L 50/51; B60L 2210/40; H01R 2201/26

(57) ABSTRACT

A system may include a printed circuit board (PCB), wherein the PCB includes an opening. A system may include a transformer including: a housing including a first end extending in a first plane and a second end extending in a second plane, the second end configured to be inserted into the opening in the PCB; and one or more leads extending from the housing, wherein an end of the one or more leads is configured to be connected to the PCB and to be disposed between the first plane and the second plane.

### TECHNICAL FIELD

Various embodiments of the present disclosure relate generally to an automotive transformer, and, more particularly, to a low-profile transformer.

### BACKGROUND

For an inverter, a transformer is considered to be an important component of a power conversion system. However, the connections of a transformer to a printed circuit board may complicate the structural design of the components within the inverter.

The present disclosure is directed to overcoming one or more of these above-referenced challenges.

### SUMMARY OF THE DISCLOSURE

In some aspects, the techniques described herein relate to a system including: an inverter to convert DC power from a battery to AC power to drive a motor, wherein the inverter includes: a printed circuit board (PCB), wherein the PCB includes an opening; and a transformer including: a housing including a first end extending in a first plane and a second end extending in a second plane, the second end configured to be inserted into the opening in the PCB; and one or more leads extending from the housing, wherein an end of the one or more leads is configured to be connected to the PCB and to be disposed between the first plane and the second plane.

In some aspects, the techniques described herein relate to a system, wherein the one or more leads include one or more of a press fit lead or a solder lead.

In some aspects, the techniques described herein relate to a system, wherein the one or more leads include a press fit lead, and wherein an insertion depth of the second end in the opening in the PCB is dependent on a height of the first end.

In some aspects, the techniques described herein relate to a system, wherein: the inverter further includes a first thermal pad disposed on the first end, and a second thermal pad disposed on the second end, and the transformer is disposed between the first thermal pad and the second thermal pad.

In some aspects, the techniques described herein relate to a system, wherein: the PCB includes a first side and a second side, the first end is disposed on the first side of the PCB, and the second end is disposed on the second side of the PCB.

In some aspects, the techniques described herein relate to a system, wherein: the transformer further includes a cover disposed on a first side of the first thermal pad, and a plate disposed on a second side of the second thermal pad, and the first side of the first thermal pad is opposite to the second side of the second thermal pad.

In some aspects, the techniques described herein relate to a system, wherein the one or more leads extend in a direction toward the second end and perpendicular to the first end.

In some aspects, the techniques described herein relate to a system, wherein the one or more leads further include: a transformer connection end, wherein the transformer connection end of the one or more leads and the first end of the housing are configured to be disposed on a first side of the PCB; and a PCB connection end, wherein the PCB connection end of the one or more leads and the second end of the housing are configured to be disposed on a second side of the PCB.

In some aspects, the techniques described herein relate to a system, wherein the second end inserted into the opening in the PCB lowers a center of gravity of the transformer in the PCB.

In some aspects, the techniques described herein relate to a system, wherein lowering the center of gravity of the transformer reduces one or more of a vibration, a thermal stress, or a shock relative to a surface mount transformer.

In some aspects, the techniques described herein relate to a system, further including: the battery configured to supply the DC power to the inverter; and the motor configured to receive the AC power from the inverter to drive the motor, wherein the system is provided as a vehicle including the inverter, the battery, and the motor.

In some aspects, the techniques described herein relate to a system including a transformer, the transformer including: a housing including a first end and a second end, wherein the first end is opposite to the second end; and one or more leads disposed at the first end and disposed substantially perpendicular to the first end in a direction of the second end.

In some aspects, the techniques described herein relate to a system, wherein the one or more leads include a press fit lead, and wherein an insertion depth of the second end in an opening in a PCB is dependent on a height of the first end.

In some aspects, the techniques described herein relate to a system, further including: a first thermal pad disposed on the first end; a second thermal pad disposed on the second end, wherein the transformer is disposed between the first thermal pad and the second thermal pad; a cover disposed on a first side of the first thermal pad; and a plate disposed on a second side of the second thermal pad, wherein the first side of the first thermal pad is opposite to the second side of the second thermal pad.

In some aspects, the techniques described herein relate to a system, wherein the one or more leads further include: a transformer connection end, wherein the transformer connection end of the one or more leads and the first end of the housing are configured to be disposed on a first side of a PCB; and a PCB connection end, wherein the PCB connection end of the one or more leads and the second end of the housing are configured to be disposed on a second side of the PCB.

In some aspects, the techniques described herein relate to a system, further including an inverter including the transformer.

In some aspects, the techniques described herein relate to a system including: a printed circuit board (PCB), wherein the PCB includes an opening; and a transformer including: a housing includes a first end extending in a first plane and a second end extending in a second plane, the second end configured to be inserted into the opening in the PCB; and one or more leads extend from the housing, and an end of the one or more leads configured to be connected to the PCB are between the first plane and the second plane.

In some aspects, the techniques described herein relate to a system, wherein the one or more leads extend in a direction toward the second end and perpendicular to the first end.

In some aspects, the techniques described herein relate to a system, wherein the one or more leads include a press fit lead, and wherein an insertion depth of the second end in the opening in the PCB is dependent on a height of the first end.

In some aspects, the techniques described herein relate to a system, wherein the transformer is configured to be mounted in the opening in the PCB so that the first end of the housing is on a first side of the PCB, and the second end of the housing is on a second side of the PCB opposite to the first side.

Additional objects and advantages of the disclosed embodiments will be set forth in part in the description that follows, and in part will be apparent from the description, or may be learned by practice of the disclosed embodiments. The objects and advantages of the disclosed embodiments will be realized and attained by means of the elements and combinations particularly pointed out in the appended claims.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 depicts an exemplary system infrastructure for a vehicle including a combined inverter and converter, according to one or more embodiments.

FIG. 2 depicts an exemplary transformer, according to one or more embodiments.

FIG. 3 depicts an exemplary transformer, according to one or more embodiments.

FIG. 4 depicts an isolated view of the exemplary transformer of FIG. 3, according to one or more embodiments.

FIG. 5 depicts a cutaway view of the exemplary transformer of FIG. 3, according to one or more embodiments.

FIG. 6 depicts an inverted view of the exemplary transformer of FIG. 3, according to one or more embodiments.

FIG. 7 depicts a side view of the exemplary transformer of FIG. 3, according to one or more embodiments.

FIG. 8 depicts a cutaway view of an exemplary transformer in a connected system, according to one or more embodiments.

### DETAILED DESCRIPTION OF EMBODIMENTS

Both the foregoing general description and the following detailed description are exemplary and explanatory only and are not restrictive of the features, as claimed. As used herein, the terms “comprises,” “comprising,” “has,” “having,” “includes,” “including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, unless stated otherwise, relative terms, such as, for example, “about,” “substantially,” and “approximately” are used to indicate a possible variation of +10% in the stated value. In this disclosure, unless stated otherwise, any numeric value may include a possible variation of +10% in the stated value.

Various embodiments of the present disclosure relate generally to an automotive transformer, and, more particularly, to a low-profile transformer.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section.

Surface mount devices (SMD) include transformers that are designed to be soldered directly onto a printed circuit board (PCB). Through-hole transformers are designed to have the leads pass through holes in the PCB and the tips are soldered to the other side of the PCB. The use of SMD components limit which side of the PCB the component can be placed, along with the lack of physical robustness in high vibration environments. Repair and rework of SMD's may be challenging due to soldering and resoldering the leads. The use of through-hole components also limit which side of the PCB the component may be placed, along with increased assembly cost and time due to the alignment requirements.

Additionally, the choice between SMD and through-hole components is largely based on the specific requirements of the electronic device in question. Factors such as, device size, cost, production volume, environmental exposure, power handling, and mechanical stress all influence which component type is more appropriate. In practice, many electronic device designs use a mixture of both SMD and through-hole components to balance these various factors effectively. Even using a combination of SMD and through-hole components, the designs still require the component to be placed on a specific side of the PCB, which may cause issues with packaging constraints. In addition, the designs require the use of additional soldering processes, materials, and machines to adhere the transformer t the PCB.

Transformers for power supplies are large and consume volume within the electronics volume they are located. In addition, transformers tend to crack under vibration. Manufacturing requirements for soldering large electronic parts such as transformers may require that the parts only be placed on a particular side of the circuit board. Transformers may be three to four times taller than any other component on the circuit board.

One or more embodiments may replace the standard solder tail or surface mount features on the electrical parts such as transformers with a press fit connection to the PCB. An advantage of replacing the connections with press fit connections may be to allow for varying the direction and lengths of the leads and plastic housing. This approach may allow for exact proportion of the transformer housing on each side of the PCB to be customized. Optimizing the height of the component (e.g., transformer) on each side of the PCB may increase the flexibility of packaging design and may increase the ease of fitting the component into a unique system design with unique mechanical requirements while lowering the center of gravity of the component.

One or more embodiments may be configured to change the direction of the leads, which may allow the transformer to be submerged into the PCB, having a lower profile. This may allow the transformer to be supported from both the top and the bottom, increasing the vibration risk mitigation. By submerging the transformer, the center of mass of the transformer is moved from one side of the PCB to be spread between both sides of the PCB. In addition, submerging the transformer allows for cooling on both sides, reducing the windings thermal losses. Because the area of the PCB under the transformer is not used, space is not lost by submerging the transformer into the PCB. One or more embodiments may be configured to change the length of the leads and the plastic housing, allowing for customization of the vertical placements of the transformer, achieving more flexibility in overall packing of the inverter. One or more embodiments may be configured to replace or modify the lead style to include press fit leads. The press fit leads may not be required to follow manufacturing soldering requirements, allowing for placement of the transformer on either side of the PCB, which may improve flexibility.

Transformers may utilize two design variations to be mounted to a PCB, solder tail leads and surface mount leads. One or more embodiments, may utilize lead frames (e.g., transformer) that are inserted into the PCB and replace the leads with press fit technology. Utilizing press fit technology in conjunction with the transformers that are inserted (e.g., submerged) into the PCB may allow for flexibility and customization of components of the PCB around the transformer while keeping within the packaging constraints.

Press fit technology may be used in lieu of soldering components to the PCB. This may be advantageous where thermal stress from the soldering may damage sensitive components or degrade the board. The absence of solder may also reduce the concerns of solder quality, solder joint reliability under thermal cycling, and potential soldering-induced defects. Press fit connections may generally be more robust against physical stresses than surface mount connections, making them ideal for high-reliability applications where the assembly might be subjected to vibration, shock, or other mechanical stresses. Because no soldering is involved in installing the transformer, rework can be done by replacing the compliant pin header. Press fit connections may sometimes provide superior thermal and electrical performance due to the direct metal-to-metal contact. This may be particularly beneficial in high-power applications where effective heat dissipation and low electrical resistance are critical.

Press fit components may eliminate the need for manual soldering or wave soldering required from Thermal-Hydrological-Mechanical-Chemical (THMC) components, streamlining the assembly process. This may lead to faster production times and reduced labor costs. During assembly, THMCs and PCBs may be exposed to thermal stress from soldering which may cause warping or damage, especially in PCB's with finer geometries. Press fit technology may eliminate this risk, preserving the integrity of the PCB. Press fit leads may often include a more controlled impedance than THMCs, which may be crucial in high-frequency applications where maintaining signal integrity is important. Although THMCs do allow for components on both sides of the board, the drilling required may interfere with the routing of traces and limit the placement of other components. Press fit components may require less invasive board penetration, which may be integrated into denser layouts without compromising the board design.

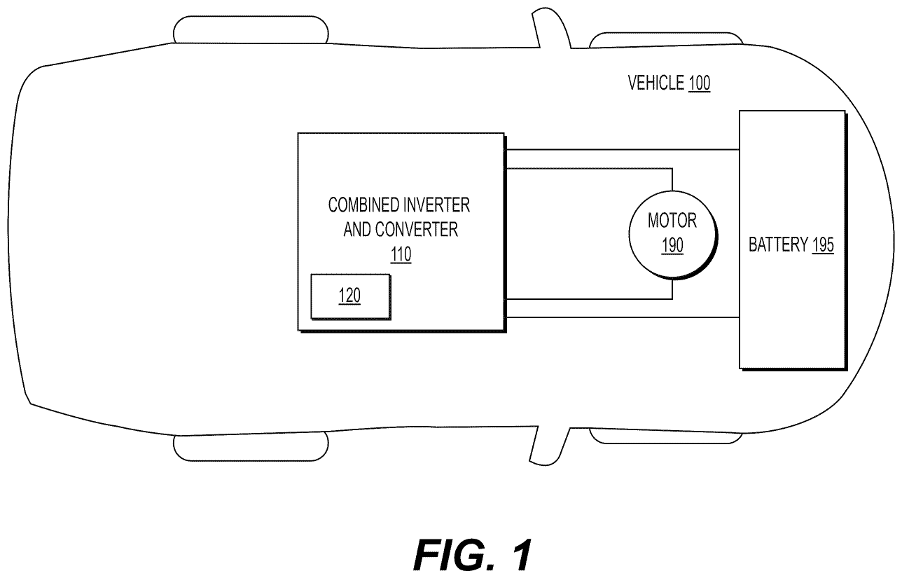

FIG. 1 depicts an exemplary system infrastructure for a vehicle including a combined inverter and converter, according to one or more embodiments. In the context of this disclosure, the combined inverter and converter may be referred to as an inverter. As shown in FIG. 1, electric vehicle 100 may include an inverter 110, a motor 190, and a battery 195. The inverter 110 may include transformer 120 and other components to receive electrical power from an external source and output electrical power to charge battery 195 of electric vehicle 100. The inverter 110 may convert DC power from battery 195 in electric vehicle 100 to AC power, to drive motor 190 of the electric vehicle 100, for example, but the embodiments are not limited thereto. The inverter 110 may be bidirectional, and may convert DC power to AC power, or convert AC power to DC power, such as during regenerative braking, for example. Inverter 110 may be a three-phase inverter, a single-phase inverter, or a multi-phase inverter.

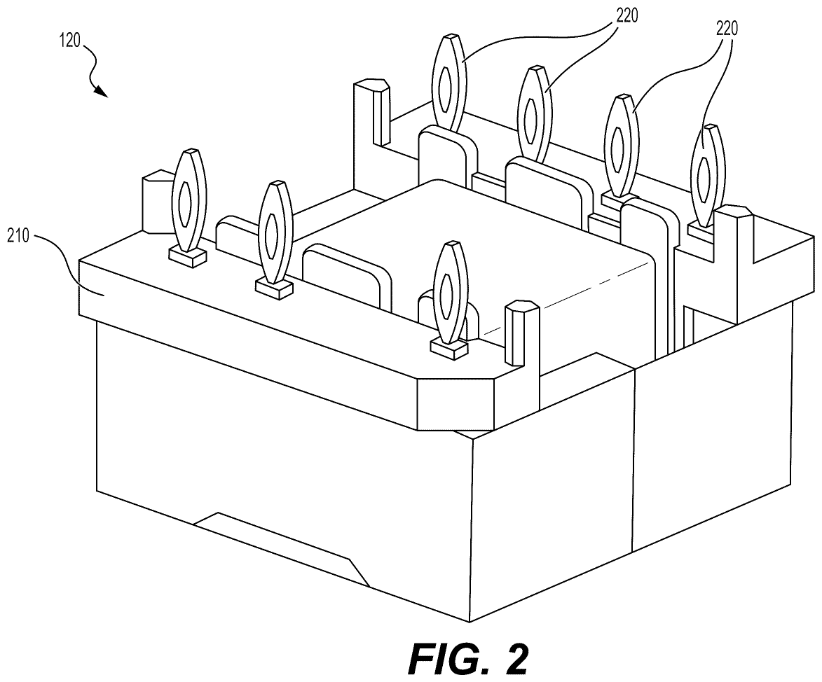

FIG. 2 depicts an exemplary transformer, according to one or more embodiments. Transformer 120 may include housing 210 and leads 220. The housing 210 may surround a body of the transformer 120. The leads 220 may include one or more of press fit leads or solder leads. The leads 220 may be disposed at one end of the transformer 120 extending in the outward direction. The transformer 120 may be configured to be part of the inverter 110 within a system, wherein the system is provided as a vehicle (e.g., electric vehicle 100) including the inverter 110, the battery 195, and the motor 190.

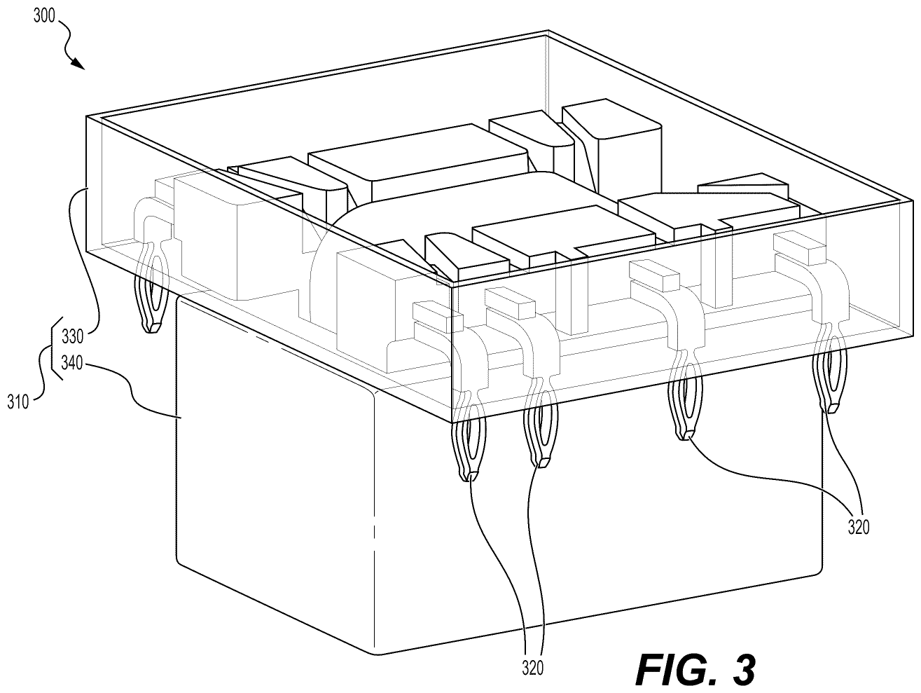

FIG. 3 depicts an exemplary transformer, according to one or more embodiments. Transformer 300 may be similar to the transformer 120 as described with reference to FIG. 1 and FIG. 2. The transformer 300 may include a housing 310 and leads 320. The housing 310 may include a first end 330 extending in a first plane and a second end 340 extending in a second plane. The first plane and the second plane may be parallel to one another. The leads 320 may extend from the housing 310 so that an end of the leads 320 is configured to be between the first plane of the first end 330 and the second plane of the second end 340. The leads 320 may include one or more of press fit leads or solder leads. The leads 320 may extend in a direction toward the second end 340 and perpendicular to the first end 330.

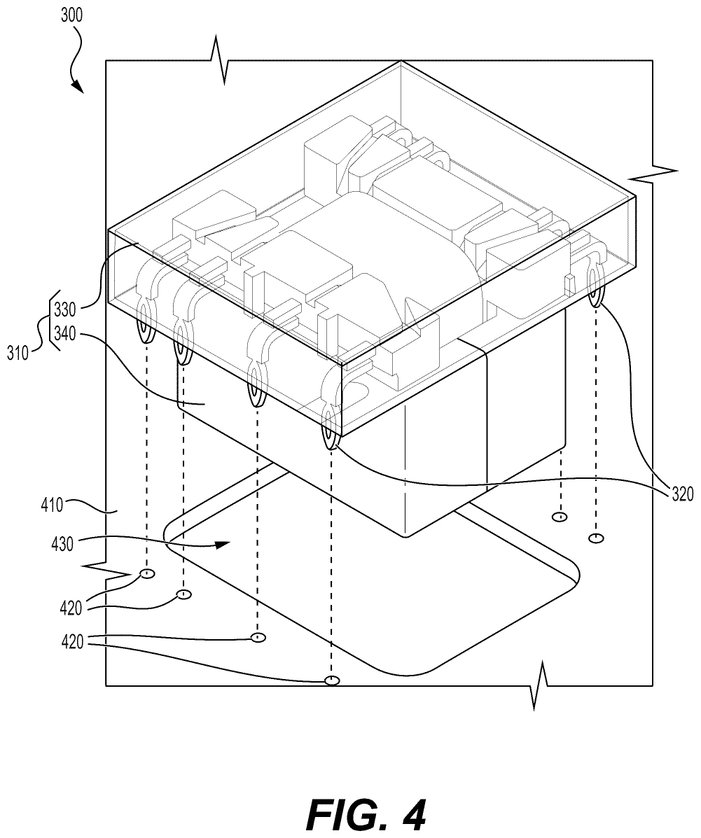

FIG. 4 depicts an isolated view of the exemplary transformer of FIG. 3, according to one or more embodiments. A PCB 410 may include an opening 430 and lead receivers 420. The opening 430 of the PCB 410 may be configured to receive the transformer 300, such that the transformer 300 is submerged into the opening 430 of the PCB 410. The lead receivers 420 of the PCB may be configured to receive the leads 320 of the transformer 300. For example, the lead receivers 420 may be a plated pad or a plated hole. The leads 320 may include one or more of press fit leads or solder leads. The leads 320 of the transformer 300 may be configured to extend through the lead receivers 420 and be operatively connected to the PCB 410. The PCB may include a first side and a second side (not shown).

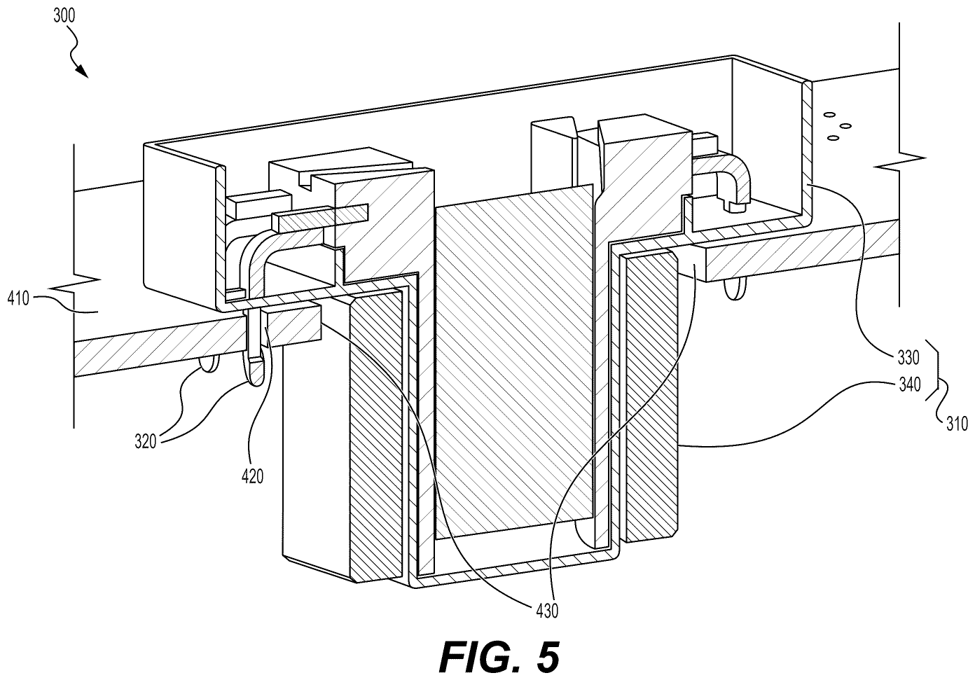

FIG. 5 depicts a cutaway view of the exemplary transformer of FIG. 3, according to one or more embodiments. The transformer 300 may be configured to be submerged into the opening 430 of the PCB 410. The leads 320 of the transformer 300 may be configured to extend through the lead receivers 420 of the PCB 410 when the transformer 300 is submerged into the opening 430 of the PCB 410. The first end 330 of the housing 310 extending in the first plane of the transformer 300 may be configured to be disposed on the first side of the PCB 410 while the second end 340 of the housing 310 extending in the second plane of the transformer 300 may be configured to be disposed on the second side of the PCB 410. A transformer connection end of the leads 320 and the first end 330 of the housing 310 may be disposed on the first side of the PCB 410. A PCB connection end of the leads 320 and the second end 340 of the housing 310 may be disposed on the second side of the PCB 410.

Advantages of submerging the transformer 300 into the PCB 410 may include having a lower profile. Because the area under the transformer 300 at the location on the PCB 410 is not used, space is not lost by submerging the transformer 300 into the PCB 410. In addition, changing the direction of the leads 320 allow for the transformer 300 to be submerged into the PCB 410. Submersion of the transformer 300 allows the transformer 300 to be supported from both the first end 330 and the second end 340, increasing the vibration risk mitigation. By submerging the transformer 300, the center of mass of the transformer 300 is moved from one side of the PCB 410 to be spread between both sides of the PCB 410.

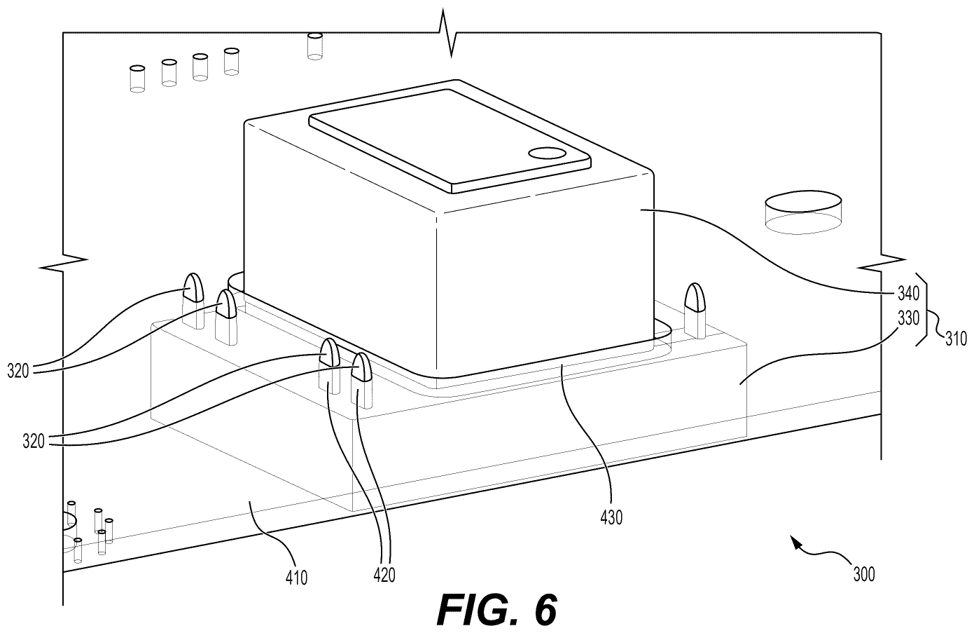

FIG. 6 depicts an inverted view of the exemplary transformer of FIG. 3, according to one or more embodiments. The transformer 300 may be configured to be submerged into the opening 430 of the PCB 410. The leads 320 of the transformer 300 may be configured to extend through the lead receivers 420 of the PCB 410 when the transformer 300 is submerged into the opening 430 of the PCB 410.

Advantages of placing the transformer 300 on either side of the PCB 410 may include further customization of the components used on the PCB 410 with the transformer 300. Utilizing press fit technology in conjunction with the transformers that are inserted (e.g., submerged) onto either side of the PCB may allow for flexibility and customization of components of the PCB around the transformer while keeping within the packaging constraints.

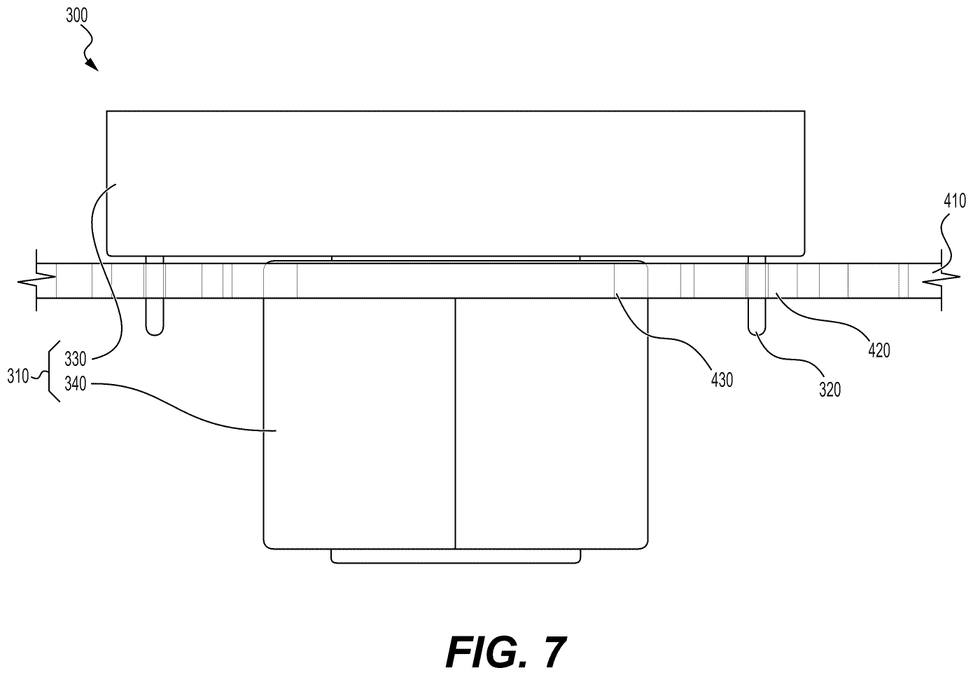

FIG. 7 depicts a side view of the exemplary transformer of FIG. 3, according to one or more embodiments. The transformer 300 may be configured to be submerged into the opening 430 of the PCB 410. The leads 320 of the transformer 300 may be configured to extend through the lead receivers 420 of the PCB 410 when the transformer 300 is submerged into the opening 430 of the PCB 410. The leads 320 may be adjustable to different lengths to allow for customization of the placement of the first end 330 and the second end 340 with respect to the PCB 410. The height of the first end 330 may also be changed. The length of the leads 320 may include an insertion depth, where the insertion depth of the second end 340 in the opening 430 in the PCB 410 is dependent on a length of the leads 320. For example, the length of the leads 320 may be configured to be disposed from the first end 330 of the housing 310 of the transformer 300 a first distance from the first side of the PCB 410. The second end 340 of the housing 310 of the transformer 300 may be disposed a second distance from the second side of the PCB, where the first distance and the second distance are different. The first end 330 of the housing 310 extending in the first plane of the transformer 300 may be configured to be disposed on the first side of the PCB 410 while the second end 340 of the housing 310 extending in the second plane of the transformer 300 may be configured to be disposed on the second side of the PCB 410. The leads 320 may be operatively connected to the second side of the PCB 410.

Advantages of including leads 320 configured to be adjustable may include the ability to optimize the height of the transformer 300 on each side of the PCB 410. In addition, adjustable leads may increase flexibility of packaging design along with the ease of fitting the transformer 300 into a different system design having different mechanical requirements.

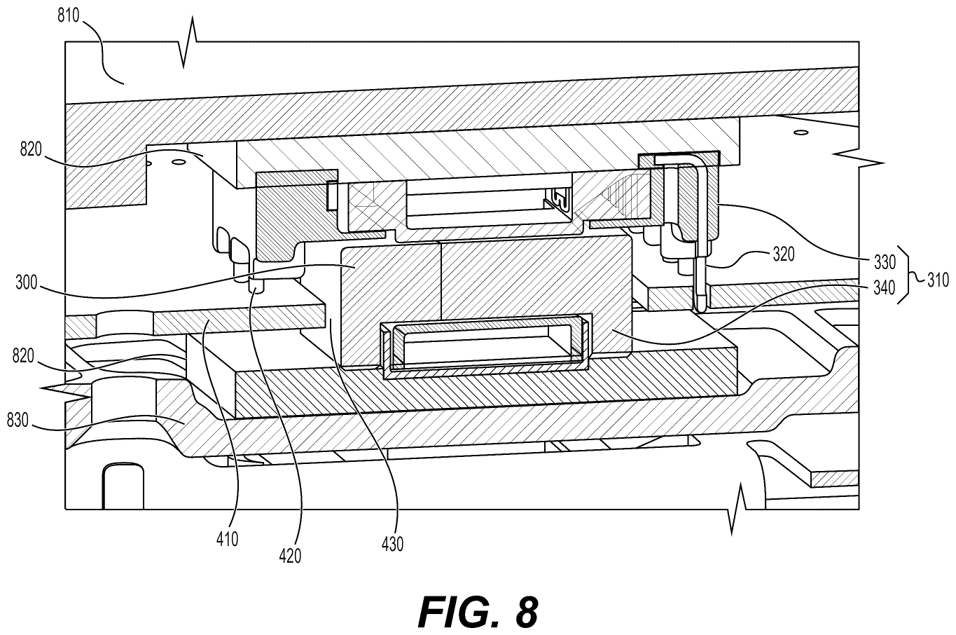

FIG. 8 depicts a cutaway view of an exemplary transformer in a connected system, according to one or more embodiments. The inverter 110 may include the transformer 300 submerged into the opening 430 of the PCB 410. The inverter 110 may include one or more thermal pads 820. A first thermal pad of the one or more thermal pads 820 may be disposed on the first end 330 of the housing 310 of the transformer 300. A second thermal pad of the one or more thermal pads 820 may be disposed on the second end 340 of the housing 310 of the transformer 300. The transformer 300 may be configured to be disposed between the first thermal pad and the second thermal pad of the one or more thermal pads 820.

The inverter 110 may include a cover 810 and a plate 830. The cover 810 may be a cast aluminum cover. The plate 830 may be a cast aluminum plate. The cover 810 may be disposed on a first side of the one or more thermal pads 820. The plate 830 may be disposed on a second side of the one or more thermal pads 820. The first side of the one or more thermal pads 820 may be opposite to the second side of the one or more thermal pads 820. The transformer 300 may be disposed between the one or more thermal pads 820. The one or more thermal pads 820 may be disposed between the cover 810 and the plate 830.

Advantages of including the one or more thermal pads 820 may include the ability to support the transformer 300 from both the first end 330 and the second end 340 of the housing 310, increasing the vibration risk mitigation. In addition, submerging the transformer 300 may allow for cooling on both sides (e.g., first end 330 and the second end 340 of the housing 310), reducing the windings thermal losses. Utilizing press fit technology in lieu of soldering may be advantageous where thermal stress from the soldering may damage sensitive components or degrade the board. The absence of solder may also reduce the concerns of solder quality, solder joint reliability under thermal cycling, and potential soldering-induced defects. Press fit connections may be more robust against physical stresses, making them ideal for high-reliability applications where the assembly might be subjected to vibration, shock, or other mechanical stresses. Rework may be done by replacing the compliant pin header in press fit connections. Press fit connections may provide superior thermal and electrical performance due to the direct metal-to-metal contact. This may be particularly beneficial in high-power applications where effective heat dissipation and low electrical resistance are critical.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A system comprising:
an inverter to convert DC power from a battery to AC power to drive a motor, wherein the inverter includes:
a printed circuit board (PCB), wherein the PCB includes an opening; and
a transformer including:
a housing including a first end extending in a first plane and a second end extending in a second plane, the second end configured to be inserted into the opening in the PCB; and
one or more leads extending from the housing, wherein an end of the one or more leads is configured to be connected to the PCB and to be disposed between the first plane and the second plane.

2. The system of claim 1, wherein the one or more leads include one or more of a press fit lead or a solder lead.

3. The system of claim 1, wherein the one or more leads include a press fit lead, and wherein an insertion depth of the second end in the opening in the PCB is dependent on a height of the first end.

4. The system of claim 1, wherein:
the inverter further includes a first thermal pad disposed on the first end, and a second thermal pad disposed on the second end, and
the transformer is disposed between the first thermal pad and the second thermal pad.

5. The system of claim 4, wherein:
the PCB includes a first side and a second side,
the first end is disposed on the first side of the PCB, and
the second end is disposed on the second side of the PCB.

6. The system of claim 4, wherein:
the transformer further includes a cover disposed on a first side of the first thermal pad, and a plate disposed on a second side of the second thermal pad, and
the first side of the first thermal pad is opposite to the second side of the second thermal pad.

7. The system of claim 1, wherein the one or more leads extend in a direction toward the second end and perpendicular to the first end.

8. The system of claim 1, wherein the one or more leads further include:
a transformer connection end, wherein the transformer connection end of the one or more leads and the first end of the housing are configured to be disposed on a first side of the PCB; and
a PCB connection end, wherein the PCB connection end of the one or more leads and the second end of the housing are configured to be disposed on a second side of the PCB.

9. The system of claim 1, wherein the second end inserted into the opening in the PCB lowers a center of gravity of the transformer in the PCB.

10. The system of claim 9, wherein lowering the center of gravity of the transformer reduces one or more of a vibration, a thermal stress, or a shock relative to a surface mount transformer.

11. The system of claim 1, further comprising:
the battery configured to supply the DC power to the inverter; and
the motor configured to receive the AC power from the inverter to drive the motor, wherein the system is provided as a vehicle including the inverter, the battery, and the motor.

12. A system comprising a transformer, the transformer including:
a housing including a first end and a second end, wherein the first end is opposite to the second end; and
one or more leads disposed at the first end and disposed substantially perpendicular to the first end in a direction of the second end.

13. The system of claim 12, wherein the one or more leads include a press fit lead, and wherein an insertion depth of the second end in an opening in a PCB is dependent on a height of the first end.

14. The system of claim 12, further including:
a first thermal pad disposed on the first end;
a second thermal pad disposed on the second end, wherein the transformer is disposed between the first thermal pad and the second thermal pad;
a cover disposed on a first side of the first thermal pad; and
a plate disposed on a second side of the second thermal pad, wherein the first side of the first thermal pad is opposite to the second side of the second thermal pad.

15. The system of claim 12, wherein the one or more leads further include:
a transformer connection end, wherein the transformer connection end of the one or more leads and the first end of the housing are configured to be disposed on a first side of a PCB; and
a PCB connection end, wherein the PCB connection end of the one or more leads and the second end of the housing are configured to be disposed on a second side of the PCB.

16. The system of claim 12, further comprising an inverter including the transformer.

17. A system comprising:
a printed circuit board (PCB), wherein the PCB includes an opening; and
a transformer including:
a housing includes a first end extending in a first plane and a second end extending in a second plane, the second end configured to be inserted into the opening in the PCB; and
one or more leads extend from the housing, and an end of the one or more leads configured to be connected to the PCB are between the first plane and the second plane.

18. The system of claim 17, wherein the one or more leads extend in a direction toward the second end and perpendicular to the first end.

19. The system of claim 17, wherein the one or more leads include a press fit lead, and wherein an insertion depth of the second end in the opening in the PCB is dependent on a height of the first end.

20. The system of claim 17, wherein the transformer is configured to be mounted in the opening in the PCB so that the first end of the housing is on a first side of the PCB, and the second end of the housing is on a second side of the PCB opposite to the first side.
